(19) United States
(12) Patent Application Publication
(10) Pub. No.: US 2025/0275452 A1
(43) Pub. Date: Aug. 28, 2025

(54) a-Si/AL/a-Si ABSORBING LAYERED STRUCTURE FOR LIGHT ABSORPTION WALL

(71) Applicant: Samsung Display Co., LTD., Yongin-si (KR)

(72) Inventors: Hyun Eok SHIN, Yongin-si (KR); Ju Hyun LEE, Yongin-si (KR); Yung Bin CHUNG, Yongin-si (KR)

(73) Assignee: Samsung Display Co., LTD., Yongin-si (KR)

(21) Appl. No.: 18/973,673

(22) Filed: Dec. 9, 2024

(30) Foreign Application Priority Data
Feb. 28, 2024 (KR) 10-2024-0028790

(51) Int. Cl. H10K 59/80; H10K 59/12; H10K 59/38; H10K 85/10; H10K 102/00

(52) U.S. Cl. CPC H10K 59/8792; H10K 59/1201; H10K 59/38; H10K 85/141; H10K 2102/351

(57) ABSTRACT

A display device includes a first, a second, and a third light emitting device disposed on a substrate, a first and second color conversion layer respectively disposed on the first and second light emitting device, a transmission layer disposed on the third light emitting device, and a multilayer film barrier rib structure disposed on the first color conversion layer, the second color conversion layer, and the transmission layer and including a transparent inorganic layer and a transparent organic layer alternately deposited. A light absorption layer barrier rib structure including a blackening member and a blackening protection member on the blackening member is disposed on a side surface of the multilayer film barrier rib structure, and the light absorption layer barrier rib structure has a plurality of openings respectively corresponding to the first light emitting device, the second light emitting device, and the third light emitting device.

### CROSS-REFERENCE TO RELATED APPLICATION(S)

This application claims priority to and benefits of Korean Patent Application No. 10-2024-0028790 under 35 U.S.C. § 119, filed on Feb. 28, 2024, in the Korean Intellectual Property Office (KIPO), the entire contents of which are incorporated herein by reference.

### BACKGROUND

### 1. Technical Field

The disclosure relates to a light absorption layer barrier rib structure that can absorb all light coming diagonally from the inside and outside, is durable, and can be manufactured by CVD deposition, a display device using the same and its manufacturing method.

### 2. Description of the Related Art

Among display devices, organic light emitting display devices are attracting attention as next-generation display devices because of a wide viewing angle, excellent contrast, and fast response speed.

In general, organic light emitting display devices include thin-film transistors and organic light emitting devices on a substrate, and the organic light emitting devices operate by emitting light on their own.

These organic lights emitting display devices are sometimes used as display units for small products such as mobile phones or display units for large products such as televisions.

In organic light emitting display devices, there is an increased need to provide accurate and vivid colors while providing larger and thinner displays.

To this end, research is being actively conducted on light absorption layer barrier rib structures that suppress or prevent light leakage from organic light emitting devices.

However, there is still a problem in that the light absorption layer barrier rib structure must exceed a certain thickness in order to absorb all the oblique internal and external light, causing a side surface step coverage problem, and accelerating side damage during the patterning process of the light absorption layer barrier rib structure.

### SUMMARY

The disclosure is intended to solve several problems, including the above problems, to provide a robust light absorption layer barrier rib structure that prevents damage to the side surface of the light absorption layer barrier rib structure, protects the side surface, and is impervious to tetramethylammonium hydroxide (TMAH), a developer used in the anisotropic dry etching process, or water washing.

However, this does not limit the scope of the disclosure.

A display device according to an embodiment of the disclosure may include a first light emitting device, a second light emitting device, and a third light emitting device disposed on a substrate, a first color conversion layer disposed on the first light emitting device and a second color conversion layer disposed on the second light emitting device, a transmission layer disposed on the third light emitting device, and a multilayer film barrier rib structure disposed on the first color conversion layer, the second color conversion layer, and the transmission layer. The multilayer film barrier rib structure may include transparent inorganic layers and a transparent organic layers alternately deposited, a light absorption layer barrier rib structure including a blackening member and a blackening protection member on the blackening member may be disposed on a side surface of the multilayer film barrier rib structure, and the light absorption layer barrier rib structure may have a plurality of openings in a first light emitting area of the first light emitting device, a second light emitting area of the second light emitting device, and a third light emitting area of the third light emitting device.

The transparent inorganic layers may include a silicon nitride compound, and the transparent organic layers may include an imide-based polymer.

The transparent inorganic layers may be deposited to a thickness in a range of about 0.1K to about 1K, the transparent organic layers may be deposited to a thickness in a range of about 2K to about 4K, and a total height of the multilayer film barrier rib structure may be in a range of about 7K to about 9K.

The blackening member may include a reflective metal layer and a CVD-deposited blackening layer disposed on side surfaces of the reflective metal layer.

The reflective metal layer may include aluminum (Al), which is for low-temperature film formation, and the CVD-deposited blackening layer may include amorphous silicon.

The reflective metal layer may have a thickness in a range of about 100 Å to about 300 Å, and the CVD-deposited blackening layer may have a thickness in a range of about 500 Å to about 1,500 Å.

The blackening protective member may include SiO₂ and may be deposited by CVD to a thickness in a range of about 300 Å to about 600 Å.

A light absorption layer barrier rib structure according to an embodiment of the disclosure may include a multilayer barrier rib structure including a transparent inorganic layer and a transparent organic layer alternately deposited, a blackening member CVD-deposited on a side of the multilayer barrier rib structure, and a blackening protection member on the blackening member.

The transparent inorganic layer may include a silicon nitride compound, and the transparent organic layer may include an imide-based polymer.

The transparent inorganic layer may be deposited to a thickness in a range of about 0.1K to about 1K, the transparent organic layer may be deposited to a thickness in a range of about 2K to about 4K, and a total height of the multilayer barrier rib member may be in a range of about 7K to about 9K.

The blackening member may include a reflective metal layer and a CVD-deposited blackening layer disposed on side surfaces of the reflective metal layer.

The reflective metal layer may include aluminum (Al), which is for low-temperature film formation, and the CVD-deposited blackening layer may include amorphous silicon.

The reflective metal layer may have a thickness in a range of about 100 Å to about 300 Å, and the CVD-deposited blackening layer may have a thickness in a range of about 500 Å to about 1500 Å.

The blackening protection member may include SiO₂, and may be a light absorption layer barrier rib structure CVD-deposited to a thickness in a range of about 300 Å to about 600 Å.

A method of manufacturing a light absorption layer barrier rib structure according to an embodiment of the disclosure may include constructing a multilayer barrier rib member in which transparent inorganic layers and transparent organic layers are alternatively arranged on an upper part of a substrate by CVD deposition, patterning the multilayer barrier rib member by dry etching to form a patterned multilayer barrier rib member, forming a blackening member by CVD deposition on the patterned multilayer barrier rib member, forming a blackening member protective film on the blackening member by CVD deposition; and removing the blackening member on an upper portion and a lower portion of the multilayer barrier rib member by anisotropic dry etching.

The constructing of the multilayer barrier rib member may include stacking the transparent inorganic layers on the substrate, and stacking the transparent organic layers on top of the transparent inorganic layers, the transparent inorganic layers may include a silicon nitride compound, the transparent organic layers may include an imide-based polymer, the forming of the blackening member may include CVD-depositing a reflective metal layer using aluminum (Al), and CVD-depositing a blackening layer using amorphous silicon, and forming of the blackening member protective film may include forming the blackening member protective film using SiO₂ by CVD deposition.

A method of manufacturing a display device according to an embodiment of the disclosure may include forming a first light emitting device, a second light emitting device, and a third light emitting device on a substrate, forming a first color conversion layer on the first light emitting device, a second color conversion layer on the second light emitting device, and a transmission layer on the third light emitting device, forming a light absorption layer barrier rib structure comprising a multilayer film barrier rib structure, which is alternately deposited with a transparent inorganic layer and a transparent organic layer, on the first color conversion layer, the second color conversion layer, and the transmission layer, and CVD-depositing a blackening member on a side surface of the multilayer film barrier rib structure, and a blackening protection member on the blackening member. An aperture ratio of a plurality of openings formed in the light absorption layer barrier rib structure respectively corresponding to the first light emitting device, the second light emitting device, and the third light emitting device may be different.

The forming of the light absorption layer barrier rib structure may include constructing a multilayer barrier rib member in which the transparent inorganic layer and the transparent organic layer are alternatively disposed on the substrate by CVD deposition, patterning the multilayer barrier rib member by dry etching to form a patterned multilayer barrier rib member, forming a blackening member by CVD deposition on the patterned multilayer barrier rib member, forming a blackening member protective film on the blackening member by CVD deposition, and removing the blackening member on an upper portion and a lower portion of the multilayer barrier rib member by anisotropic dry etching.

The forming of the blackening member may include CVD depositing a reflective metal layer using aluminum (Al), and a blackening layer using amorphous silicon.

The constructing of the multilayer barrier rib structure may include constructing a multilayer structure in which the transparent inorganic layer is stacked on the substrate and the transparent organic layer is stacked on top of the transparent inorganic layer, the transparent inorganic layer may include silicon nitride compound, the transparent organic layer may include an imide-based polymer, and the forming of the blackening member protective film may include forming the blackening member protective film using SiO₂ by CVD deposition.

Tetramethylammonium hydroxide TMAH, a developer used in the anisotropic dry etching process, may prevent damage to the sides of the MTO/Mo/MTO triple layer sandwich light absorption layer barrier rib structure and protect the sides according to an embodiment of the disclosure, alternatively, it is possible to provide a robust light absorption layer barrier rib structure that is not affected by water washing.

According to the light absorption layer barrier rib structure according to an embodiment of the disclosure, a triple-layer blackening member 5205 may be formed on the side of the multilayer barrier rib member by chemical vapor deposition of aluminum (Al) and amorphous silicon (a-Si), thereby forming a fine structure, the step coverage, which defines the thickness ratio of the upper and lower sediment layers in the depth direction, may be improved, and a low-reflection thin-film structure may be formed using a-Si/Al/a-Si blackening film.

According to the light absorption layer barrier rib structure according to an embodiment of the disclosure, the MTO/Mo/MTO triple-layer light absorption layer may be formed on the organic film barrier rib member, and the organic film barrier rib member may be formed by a low-temperature process, and although there may be a problem in that the barrier rib member may be unstable, the stability of the barrier rib structure may be secured with the cross-lamination structure of a transparent inorganic layer (SiO₂ or SiNₓ)/transparent organic layer.

According to an embodiment of the disclosure, the blackening film protective layer may prevent the sides of the light absorption layer barrier rib structure from being damaged by the developer or cleaning solution when the upper and lower parts of the light absorption layer barrier rib structure are removed.

It can be seen that the light absorption layer barrier rib structure according to an embodiment of the disclosure may transmit light close to the vertical with respect to the multilayer barrier rib member in which transparent organic layers and transparent inorganic layers are alternately laminated, and oblique internal light incident is transmitted, alternatively, it can be seen that all external light is absorbed by the CVD blackening layer on which the amorphous silicon (a-Si) of the blackening member formed on the side of the multilayer barrier rib member may be CVD-deposited.

### BRIEF DESCRIPTION OF THE DRAWINGS

FIG. 1 is a plan view of a display device according to an embodiment of the disclosure.

FIG. 2 is a schematic cross-sectional view of a display device according to an embodiment of the disclosure.

FIG. 3 is a schematic cross-sectional view of a display device according to an embodiment of the disclosure.

FIG. 4 is a schematic cross-sectional view of the light absorption layer barrier rib structure according to an embodiment of the disclosure.

FIG. 5 is a schematic cross-sectional view of a light absorption layer barrier rib structure according to an embodiment of another aspect of the disclosure.

FIG. 6 is a schematic cross-sectional view showing the optical path of the light absorption layer barrier rib structure of FIG. 5.

FIG. 7 is a flow chart showing a method of manufacturing a light absorption layer barrier rib structure according to an embodiment of another aspect of the disclosure.

FIG. 8 is a schematic diagram showing a method of manufacturing a light absorption layer barrier rib structure according to an embodiment of another aspect of the disclosure.

FIG. 9 is a schematic diagram of maximizing low-reflection effects.

FIG. 10 is a graph showing the relationship between the extinction coefficient and transmittance of the medium.

FIG. 11 is a graph showing reflectance according to the thickness of the blackening layer formed on the reflective metal layer.

FIG. 12 is a graph showing blackening film characteristics due to interference and absorption by reflection of the reflective metal layer.

FIG. 13 is a graph showing the transmittance by a-Si film thickness based on glass.

FIG. 14 is a graph of reflectance according to amorphous silicon film thickness when an amorphous silicon film is formed on an aluminum (Al) reflective metal layer.

FIG. 15 is a graph showing the reflectance by a-Si thickness of the a-Si/Al/a-Si blackening film structure.

FIG. 16 is a graph showing reflectance by a-Si thickness of a-Si/Ti/a-Si blackening film structure.

### DETAILED DESCRIPTION OF THE EMBODIMENTS

Since the disclosure can be modified in various ways and can have various embodiments, specific embodiments will be illustrated in the drawings and described in detail in the detailed description.

The effects and features of the disclosure and methods for achieving them will become clear by referring to the embodiments described in detail below along with the drawings.

However, the disclosure is not limited to the embodiments disclosed below and may be implemented in various forms.

Hereinafter, embodiments of the disclosure will be described in detail with reference to the accompanying drawings, and when described with reference to the drawings, identical or corresponding components will be assigned the same reference numerals and reference symbols and redundant description thereof will be omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, (“a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In this specification, the x-axis, y-axis, and z-axis are not limited to the three axes in the Cartesian coordinate system, but can be interpreted in a broad sense as including these.

For example, the x-axis, y-axis, and z-axis may be orthogonal to each other, but may also refer to different directions that are not orthogonal to each other.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, the display device 1 according to an embodiment of the disclosure will be described by taking an organic light emitting display device as an example, but the display device of the disclosure is not limited thereto.

As another example, the display device 1 of the disclosure may be an inorganic light emitting display or a display device such as a quantum dot light emitting display.

For example, the display element provided in the display device 1, for example, the light emitting layer of the light emitting device, may include an organic material, an inorganic material, quantum dots, an organic material, and a quantum dot, or an inorganic material and a quantum dot.

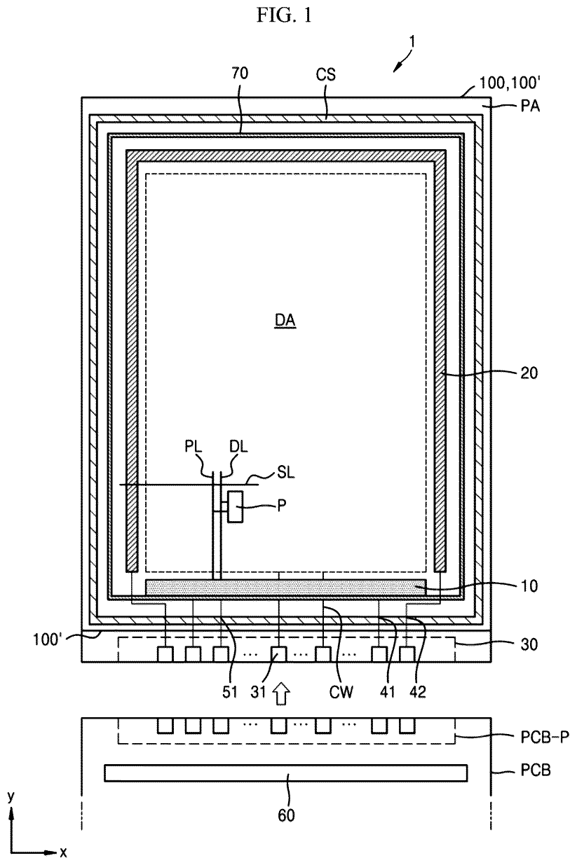

FIG. 1 is a plan view of a display device according to an embodiment of the disclosure.

Referring to FIG. 1, the display device may include a display area DA and a peripheral area PA disposed adjacent to the display area DA.

A display device may provide an image using light emitted from multiple pixels P arranged in the display area DA.

Hereinafter, in this specification, a pixel P may mean a sub-pixel that substantially includes one organic light emitting diode.

The display area DA may include pixels P connected to a data line DL extending in the y-direction and a scan line SL extending in the x-direction intersecting the y-direction.

Each pixel P may be also connected to a driving voltage line PL extending in the y-direction.

Each pixel P may include a light emitting device such as an organic light emitting diode OLED.

Each pixel P may emit, for example, red, green, blue, or white light through an organic light emitting diode OLED.

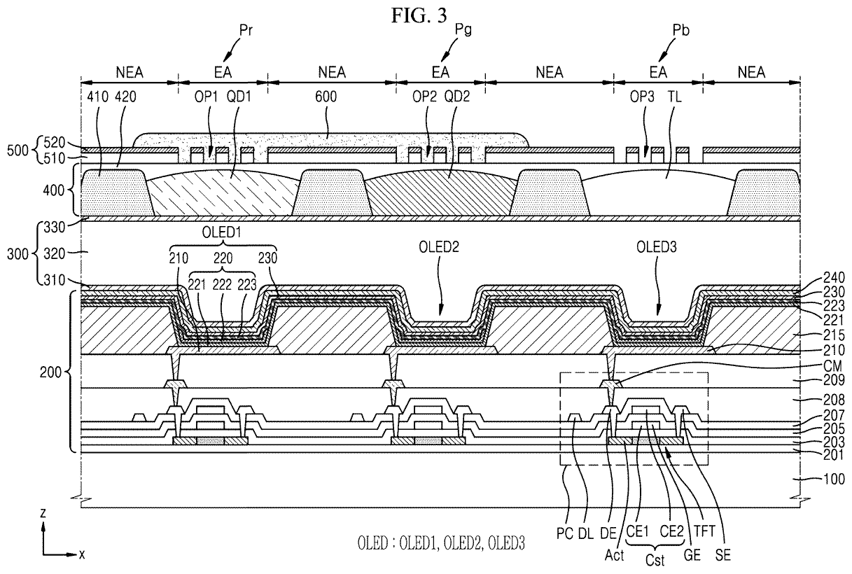

For example, the pixels P may implement the color of each pixel P independently from the color emitted by the organic light emitting diodes OLED included in each pixel P, by means of the color conversion layer (QD1, QD2, see FIG. 3) placed on top of the organic light emitting diodes OLED.

Each pixel P may be electrically connected to built-in circuits arranged in the peripheral area PA.

A first power supply wire 10, a second power supply wire 20, and a pad portion 30 may be disposed in the peripheral area PA.

The first power supply wire 10 may be arranged to correspond to a side of the display area DA. The first power supply wire 10 may be connected to multiple driving voltage lines PL that transmit driving voltage to the pixel P.

The second power supply wire 20 may have a loop shape with a side open and may partially surround the display area DA in a plan view.

The pad portion 30 may include multiple pads 31 and may be disposed on a side of a substrate 100.

Each pad 31 may be connected to a first connection wire 41 connected to the first power supply wire 10 or connection wires CW extending to the display area DA.

The pads 31 of the pad portion 30 may be exposed without being covered by an insulating layer and may be electrically connected to a printed circuit board PCB.

A terminal portion PCB-P of the printed circuit board PCB may be electrically connected to the pad portion 30.

The printed circuit board PCB may transmit signals or power from the control unit (not shown) to the pad portion 30.

The control unit may provide a driving voltage and a common voltage to the first and second power supply wires 10 and 20, respectively, through the first and second connection wires 41 and 42.

The data driving circuit 60 may be electrically connected to the data line DL.

The data signal of the data driving circuit 60 may be provided to each pixel P through the connection wire CW connected to the pad portion 30 and the data line DL connected to the connection wire CW.

A dam portion 70 may be disposed in the peripheral area PA.

The dam portion 70 may block organic substances from flowing toward the edge of the substrate 100 when forming an organic encapsulation layer 320 of a thin-film encapsulation layer 300, thereby preventing the formation of edge tails of the organic encapsulation layer 320.

The dam portion 70 may surround at least a portion of the display area DA in the peripheral area PA.

The dam portion 70 may include multiple dams, and the dams may be spaced apart from each other.

The dam portion 70 may be disposed closer to the display area DA than to a sealing member CS in a peripheral area PA.

In an embodiment, the peripheral area PA may further be provided with a built-in driving circuit (not shown) that provides scan signals for each pixel.

In some embodiments, the built-in driving circuit part and the dam portion 70 may overlap in a plan view.

The display device 1 may be formed by bonding the substrate 100 and the upper substrate 100′ by a sealing member CS.

The sealing member CS may surround the display area DA along the peripheral area PA of the substrate 100 and bond the substrate 100 and the upper substrate 100′.

In an embodiment, in case that the display device 1 has flexible characteristics, the upper substrate 100′ and the sealing member CS may be omitted.

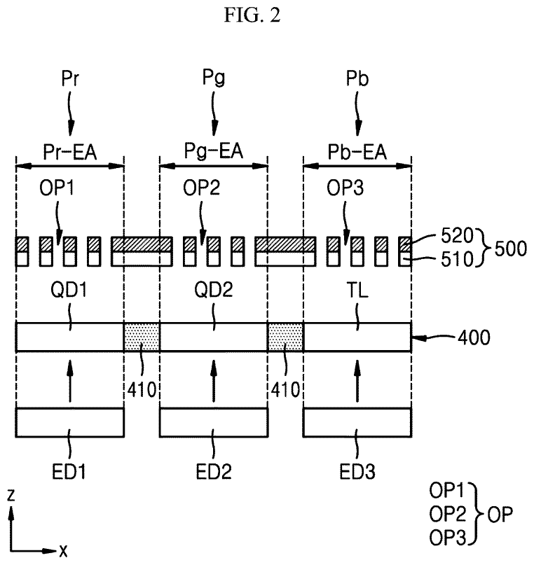

FIG. 2 is a schematic cross-sectional view of a display device according to an embodiment of the disclosure.

Referring to FIG. 2, a first pixel Pr, a second pixel Pg, and a third pixel Pb may include a first light emitting device ED1, a second light emitting device ED2, and a third light emitting device ED3, respectively.

The first light emitting device ED1, the second light emitting device ED2, and the third light emitting device ED3 may be arranged to be spaced apart from each other.

The first light emitting device ED1, the second light emitting device ED2, and the third light emitting device ED3 may emit light and function as a light source.

For example, the first light emitting device ED1, the second light emitting device ED2, and the third light emitting device ED3 may each be an organic light emitting diode OLED.

However, the disclosure is not limited thereto, and the first light emitting device ED1, the second light emitting device ED2, and the third light emitting device ED3 may be another light source.

In another embodiment, the first light emitting device ED1, the second light emitting device ED2, and the third light emitting device ED3 may emit inorganic light or quantum dot light.

A wavelength control layer 400 may be located on the first light emitting device ED1, the second light emitting device ED2, and the third light emitting device ED3.

The wavelength control layer 400 may include a first color conversion layer QD1 corresponding to the first light emitting device ED1, a second color conversion layer QD2 corresponding to the second light emitting device ED2, and a transmission layer TL corresponding to the third light emitting device ED3.

The first color conversion layer QD1 and the second color conversion layer QD2 may each include quantum dots.

The wavelength of light passing through the first color conversion layer QD1 and the second color conversion layer QD2 may be changed by quantum dots.

The transmission layer TL may not include quantum dots, and therefore, light passing through the transmission layer TL may be emitted to the outside without changing the wavelength.

A barrier rib 410 may be positioned between the first color conversion layer QD1, the second color conversion layer QD2, and the transmission layer TL.

The barrier rib 410 may include a light blocking material in an embodiment.

An optical functional layer 500 may be disposed on the wavelength control layer 400.

The optical functional layer 500 may include multiple openings OP formed in a first light emitting area Pr-EA of the first light emitting device ED1, a second light emitting area Pg-EA of the second light emitting device ED2, and a third light emitting area Pb-EA of the third light emitting device ED3.

In an embodiment, the openings OP may include first openings OP1 corresponding to the first light emitting area Pr-EA, second openings OP2 corresponding to the second light emitting area Pg-EA, and third openings OP3 corresponding to the third light emitting area Pb-EA.

Each of the first openings OP1, second openings OP2, and third openings OP3 may be provided to have an aperture ratio for each pixel.

FIG. 3 is a schematic cross-sectional view of a display device according to an embodiment of the disclosure.

Referring to FIG. 3, the first to third pixels Pr, Pg, Pb may be disposed on the substrate 100.

The first to third pixels Pr, Pg, Pb may each include the first to third light emitting devices and a pixel circuit PC, and each of the first to third light emitting devices may be electrically connected to the pixel circuit PC so that light emission may be controlled.

In an embodiment, the first to third light emitting devices may be the first to third organic light emitting diodes OLED1, OLED2, OLED3.

In the following description, since the pixel circuits PC included in each of the first to third pixels Pr, Pg, Pb have a same structure, the stacked structure will be described below with a focus on one pixel.

In an embodiment, the substrate 100 may include glass or a polymer resin.

In an embodiment, the substrate 100 may include multiple sub-layers.

The sub-layers may have a structure in which organic layers and inorganic layers are alternately stacked each other.

A display layer 200 including a light emitting device and a thin-film encapsulation layer 300 covering the display layer 200 may be disposed on the substrate 100.

Hereinafter, the display layer 200 will be described in detail.

A buffer layer 201 may be formed on the substrate 100 to prevent impurities from penetrating into the semiconductor layer Act of a thin-film transistor TFT.

The buffer layer 201 may be a single layer or multiple layers containing an inorganic insulating material.

A pixel circuit PC may be disposed on the buffer layer 201.

The pixel circuit PC may be arranged to correspond to each pixel P.

The pixel circuit PC may include a thin-film transistor TFT and a storage capacitor Cst.

A thin-film transistor TFT may include a semiconductor layer Act, a gate electrode GE, a source electrode SE, and a drain electrode DE.

The storage capacitor Cst may include a first electrode CE1 and a second electrode CE2 that overlap each other in a plan view with a first interlayer insulating layer 205 interposed between the first electrode CE1 and the second electrode CE2.

The storage capacitor Cst may overlap the thin-film transistor TFT in a plan view.

The pixel circuit PC including the thin-film transistor TFT and the storage capacitor Cst may be covered with a first planarization insulating layer 208.

The first planarization insulating layer 208 may have a substantially flat upper surface.

A second interlayer insulating layer 207 may be further disposed below the first planarization insulating layer 208.

The pixel circuit PC may be electrically connected to a pixel electrode 210.

A contact metal layer CM may be interposed between the thin-film transistor TFT and the pixel electrode 210.

The contact metal layer CM may be connected to the thin-film transistor TFT through a contact hole formed in the first planarization insulating layer 208, and the pixel electrode 210 may be connected to the contact metal layer CM through contact holes formed in the second planarization insulating layer 209 on the contact metal layer CM.

The first to third organic light emitting diodes OLED1, OLED2, OLED3 may be disposed on the second planarization insulating layer 209.

In an embodiment, each of the first to third organic light emitting diodes OLED1, OLED2, OLED3 may include a pixel electrode 210, a first common layer 221, a light emitting layer 222, a second common layer 223, and an opposing electrode 230.

In the first to third organic light emitting diodes OLED1, OLED2, OLED3, the pixel electrode 210 and the light emitting layer 222 may be patterned and provided for each pixel, and the first common layer 221, the second common layer 223, and the counter electrode 230 may be provided integrally in the display area.

A pixel defining layer 215 may be formed on the pixel electrode 210.

The pixel defining layer 215 may include an opening that exposes a top surface of the pixel electrode 210 and may cover edges of the pixel electrode 210.

A middle layer 220 may include a light emitting layer 222.

The light emitting layer 222 may include a polymer or low-molecular organic material that emits light of a color.

In an embodiment, the middle layer 220 may include a first common layer 221 located between the light emitting layer 222 and the pixel electrode 210, and/or a second common layer 223 located between the light emitting layer 222 and the counter electrode 230.

A capping layer 240 may be positioned on the counter electrode 230.

For example, the capping layer 240 may include an organic material, an inorganic material, or a mixture thereof and may be provided as a single layer or multiple layers.

Since the first to third organic light emitting diodes OLED1, OLED2, OLED3 may be readily damaged by moisture or oxygen from the outside, the first to third organic light emitting diodes OLED1, OLED2, OLED3 can be protected by being covered with a thin-film encapsulation layer 300.

The thin-film encapsulation layer 300 may cover the display area DA and may extend to a non-display area outside the display area DA.

The thin-film encapsulation layer 300 may include at least one organic encapsulation layer and at least one inorganic encapsulation layer.

For example, the thin-film encapsulation layer 300 may include a first inorganic encapsulation layer 310, an organic encapsulation layer 320, and a second inorganic encapsulation layer 330.

Since the first inorganic encapsulation layer 310 is formed along the structure below, an upper surface of the first inorganic encapsulation layer 310 may not be flat.

The organic encapsulation layer 320 may cover the first inorganic encapsulation layer 310, and the upper surface of the first inorganic encapsulation layer 310 may be substantially flat.

The second inorganic encapsulation layer 330 may cover the organic encapsulation layer 320 and may include silicon nitride, silicon oxynitride, or silicon oxide.

Even if cracks occur in the thin-film encapsulation layer 300 through the above-described multi-layer structure, the thin-film encapsulation layer 300 may prevent such cracks from being connected between the first inorganic encapsulation layer 310 and the organic encapsulation layer 320 or between the organic encapsulation layer 320 and the second inorganic encapsulation layer 330.

Through this, it is possible to prevent or minimize the formation of a path through which moisture or oxygen from the outside penetrates into the display area.

A wavelength control layer 400 may be disposed on the thin-film encapsulation layer 300.

The wavelength control layer 400 may include color conversion layers QD1, QD2, a transmission layer TL, and a barrier rib 410.

The color conversion layers QD1, QD2 may each include quantum dots.

Quantum dots may have unique excitation and emission characteristics depending on their material and size, and thus may convert incident light into light of another color.

A variety of materials may be used as quantum dots.

The transmission layer TL, rather than a color conversion layer, may be disposed in the light emitting area EA of the third pixel Pb.

The transmission layer TL may be made of an organic material that emits light without converting the wavelength of light emitted from the third organic light emitting diode OLED3 of the third pixel Pb.

In an embodiment, the first and second organic light emitting diodes OLED1, OLED2 may emit light of a same wavelength, and the colors of the first pixel Pr and second pixel Pg may be determined according to the wavelengths altered by the quantum dots of the first color conversion layer QD1 and the quantum dots of the second color conversion layer QD2.

Since a color conversion layer is not provided in the light emitting area EA of the third pixel Pb, the third pixel Pb may be determined by the color emitted by the third organic light emitting diode OLED3.

For example, the first pixel Pr may emit red light, the second pixel Pg may emit green light, and the third pixel Pb may emit blue light.

The barrier rib 410 may be disposed between the first color conversion layer QD1, the second color conversion layer QD2, and the transmission layer TL in the non-light emitting area NEA.

For example, the barrier rib 410 may be disposed between the first color conversion layer QD1 and the second color conversion layer QD2, between the second color conversion layer QD2 and the transmission layer TL, etc.

In an embodiment, the barrier rib 410 may include an organic material, and in an embodiment, Cr, CrOₓ, Cr/CrOₓ, Cr/CrOₓ/CrN_{y}, a resin (carbon pigment, RGB mixture pigment), graphite, and a non-Cr based material for controlling optical density.

In another embodiment, the barrier rib 410 may include a pigment that has colors such as red, green, or yellow, and the barrier rib 410 may serve as a black matrix to prevent color mixing and improve visibility.

After first forming the barrier rib 410 on the thin-film encapsulation layer 300, the first color conversion layer QD1, the second color conversion layer QD2, and the transmission layer TL may be formed in the area between the barrier ribs 410.

A barrier layer 420 may be disposed on the first color conversion layer QD1, the second color conversion layer QD2, and the transmission layer TL for planarization and to prevent permeation of impurities.

The barrier layer 420 may be formed of silicon nitride, silicon oxynitride, or silicon oxide, and may have a single-layer or multi-layer structure.

An optical functional layer 500 may be disposed on the wavelength control layer 400.

The optical functional layer 500 may include a reflective metal layer 510 and a light absorption layer 520 located on the reflective metal layer 510.

The reflective metal layer 510 may include a reflective metal.

For example, the reflective metal layer 510 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof.

In an embodiment, the reflective metal layer 510 may include a metal having a high reflectivity, and the reflective metal layer 510 may have a reflectance greater than or equal to about 85%. For example, the reflective metal layer 510 may have a reflectance greater than or equal to about 90%.

The reflectance may be a value measured based on a standard light source D65.

The reflective metal layer 510 may include, for example, super aluminum (s-Al).

Super aluminum (s-Al) is a high-purity aluminum alloy, and its reflectivity may be greater than or equal to about 89%.

As such, the reflective metal layer 510 may include a reflective film metal having a high reflectivity, thereby increasing the luminous efficiency of the display device through recycling of light due to internal reflection.

The light absorption layer 520 may be disposed above the reflective metal layer 510.

The light absorption layer 520 may include a metal having an absorption coefficient.

For example, the light absorption layer 520 may include at least one of molybdenum tantalum oxide (MoTaOₓ, MTO), molybdenum (Mo), tantalum (Ta), manganese (Mn), and magnesium (Mg).

The light absorption layer 520 may prevent color mixing between pixels and improve visibility by absorbing and blocking external light.

The optical functional layer 500 may also be disposed in the non-light emitting area NEA between the light emitting areas EA.

As described above, since the light functional layer 500 includes the light absorption layer 520, the light functional layer 500 may function as a black matrix in the non-light emitting area NEA through the light absorption layer 520.

Through this, the display device 1 according to an embodiment of the disclosure may not need a separate black matrix, which simplifies the manufacturing process and reduces costs.

In an embodiment, the optical functional layer 500 may have multiple openings OP in the light emitting area EA.

The openings OP may penetrate the optical functional layer 500.

For example, multiple openings OP may be formed penetrating the reflective metal layer 510 and the light absorption layer 520.

In an embodiment, multiple openings OP may have different aperture ratios for each pixel.

“Aperture ratio” may be a concept distinguished from the absolute light emitting area or aperture area, and may be the ratio of the area of multiple apertures OP to the light emitting area EA defined by the aperture of the pixel defining layer 215, in case that the light emitting area EA is 100.

The aperture ratio of the openings OP to the light emitting area EA may be, for example, greater or equal to about 40%. For example, the aperture ratio of the openings OP to the light emitting area EA may be greater than or equal to about 45%. For example, the aperture ratio of the openings OP to the light emitting area EA may be greater than or equal to about 50%.

This may be modified according to the conditions required for each pixel.

Light emitted from the first to third organic light emitting diodes OLED1, OLED2, OLED3 may pass through multiple openings OP and be emitted to the outside.

For example, the larger the aperture ratio of the openings OP, the more advantageous it is in terms of light efficiency, but it may be vulnerable to external light reflection.

Conversely, the smaller the aperture ratio of the openings OP, the more advantageous it is for preventing external light reflection, but the amount of light blocked increases, which may lower light efficiency.

Accordingly, in the display device 1 according to an embodiment of the disclosure, the aperture ratio may be optimized by adjusting the size of the openings OP of the optical functional layer 500, and at the same time, by arranging reflective metal layer 510 on a side of the optical functional layer 500, such that some of the light that does not pass through the openings OP may be reflected and reproduced by the reflective metal layer 510, thereby increasing light efficiency.

A filter layer 600 may be disposed on the optical functional layer 500.

The filter layer 600 may be disposed to correspond only to the first pixel Pr and the second pixel Pb.

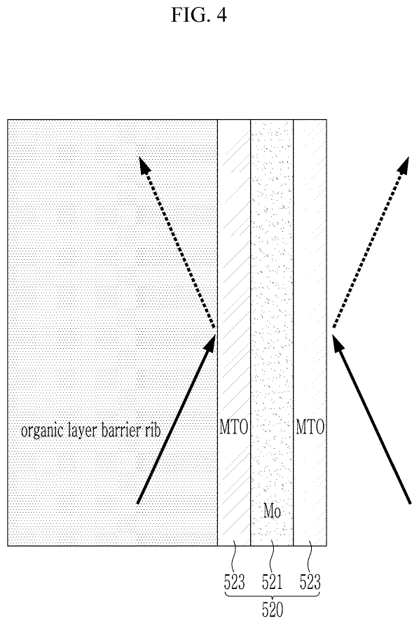

Hereinafter, the light absorption layer barrier rib structure according to an embodiment of the disclosure will be described in detail with reference to FIG. 4.

The light absorption layer barrier rib structure according to an embodiment of the disclosure may be applied to the barrier rib 410 or the light functional layer 500 that may be used as a black matrix.

FIG. 4 is a schematic cross-sectional view of a light absorption layer barrier rib structure according to an embodiment of the disclosure.

As shown in FIG. 4, according to an embodiment of the disclosure, the light absorption layer 520 barrier rib member may have a molybdenum (Mo) metal film 521 in the center and a molybdenum tantalum oxide MoTaOₓ (MTO) film 523 with an MTO/Mo/MTO triple-layer sandwich structure.

Here, molybdenum tantalum oxide MoTaOₓ (MTO) may be a light-absorbing material including tantalum (Ta) in an amount up to 6%.

With the light absorption layer barrier rib structure according to an embodiment of the disclosure, due to the interference effect of the MTO/Mo/MTO triple-layer structure composed of a molybdenum (Mo) metal film 521 in the center and a molybdenum tantalum oxide MoTaOₓ, MTO film 523 at the upper and lower sections, color mixing between pixels may be prevented and visibility may be improved by absorbing light inside and outside the light absorption layer barrier rib structure.

When forming an MTO/Mo/MTO triple-layer structure with a light absorption layer barrier rib structure according to an embodiment of the disclosure, to form an MTO/Mo/MTO triple-layer structure with a thickness on the side wall, anisotropic drying may be required for the upper and lower sections, and it may need to remove a thickness through an etching process.

In the light absorption layer barrier rib structure according to an embodiment of the disclosure, in order to make the side wall of the light absorbing layer 520 with a thickness about 72 nm with an MTO/Mo/MTO triple-layer structure, it may need to form a thick, non-uniform MTO/Mo/MTO triple-layer structure, such as 3000 μm, 1000 μm or 278 μm, for the upper and lower portions of the light absorption layer 520 which needs to be removed, and therefore may need to be removed using an anisotropic dry etching process.

If the light absorption layer 520 is composed of an MTO/Mo/MTO triple-layer structure, the blackening characteristic may be very excellent, but anisotropic drying may be required for a thick and unevenly formed MTO/Mo/MTO triple-layer structure on the top or bottom of the light absorbing layer 520, and because tetramethylammonium hydroxide TMAH, a developer used in anisotropic dry etching process, or molytantal oxide MTO, may be readily dissolved by water washing, side erosion on the sidewalls of the light absorption layer 520 may have intensified on the side wall, causing a problem of property deterioration.

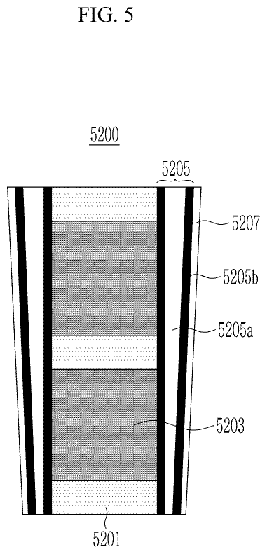

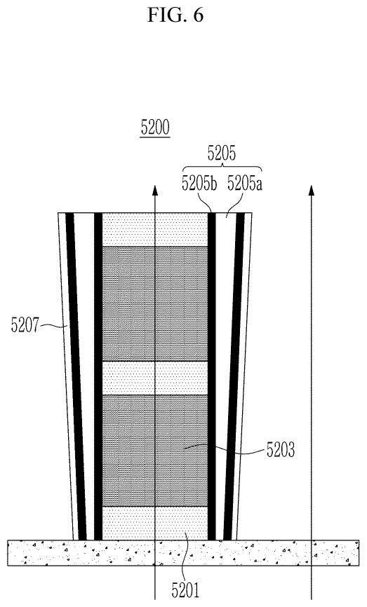

With reference to FIGS. 5 and 6, a light absorption layer barrier rib structure according to an embodiment of another aspect of the disclosure to solve this problem will be described.

The purpose of the light absorption layer barrier rib structure according to an embodiment of the disclosure is to solve this problem, and the MTO/Mo/MTO triple-layer light absorption layer barrier rib structure according to an embodiment of the disclosure, may protect the sides by preventing side damage, and provide a robust light absorption layer barrier rib structure that is not affected by water or tetramethylammonium hydroxide TMAH, a developer used in the anisotropic dry etching process.

FIG. 5 is a schematic cross-sectional view of a light absorption layer barrier rib structure according to an embodiment of another aspect of the disclosure. As shown in FIG. 5, the light absorption layer barrier rib structure 5200 according to an embodiment of the disclosure may include a multilayer barrier rib structure in which transparent inorganic layers 5201 and transparent organic layers 5203 are alternately deposited, a blackening member 5205 on the side of the multilayer barrier rib structure, and a blackening protection member 5207 for protecting the blackening member 5205.

The transparent inorganic layer 5201 may include an inorganic material such as silicon oxide, silicon nitride, silicon oxynitride, aluminum oxide, titanium oxide, tantalum oxide, and hafnium oxide.

The transparent organic layer 5203 may include a general-purpose polymer such as polymethylmethacrylate (PMMA) or polystyrene (PS), a polymer derivative with a phenolic group, an acrylic polymer, an imide polymer, an aryl ether polymer, an amide polymer, a fluorine polymer, a p-xylene polymer, a vinyl alcohol-based polymer, and a blend thereof.

In the light absorption layer barrier rib structure 5200 according to an embodiment of the disclosure, the multilayer barrier rib structure in which a transparent inorganic layer 5201 and a transparent organic layer 5203 are alternately deposited may be substantially similar to the existing organic layer single barrier rib structure, and since the member is formed through a low-temperature process, stability may be secured by solving the problem of instability.

### Example 1

In example 1, a transparent inorganic layer 5201 may be stacked, and on top of the transparent inorganic layer 5201, a transparent organic layer 5203 may be stacked, forming a multilayer structure. The transparent inorganic layer 5201 may include a silicon nitride compound (SiNₓ), and the transparent organic layer 5203 may include a polyimide-based polymer (PI: polyimide), and using CVD or PECVD methods, the SiNₓ/PI/SiNₓ/PI/SiNₓ multilayer structure may be deposited in increments of 0.5, 3.0, 0.5, 3.0, 0.5K, respectively, totaling 7.5K.

In the light absorption layer barrier rib structure 5200 according to an embodiment of the disclosure, the blackening member 5205 formed on the side of the multilayer barrier rib member may be a triple-layer structure formed by forming a reflective metal layer 5205a, sandwiching a CVD-deposited blackening layer 5205b on sides of the reflective metal layer 5205a using a chemical vapor deposition (CVD) method.

The reflective metal layer 5205a may include silver (Ag), magnesium (Mg), aluminum (Al), platinum (Pt), palladium (Pd), gold (Au), nickel (Ni), neodymium (Nd), iridium (Ir), chromium (Cr), or a compound thereof, similarly to the reflective film reflective metal layer, as may have good reflectivity.

The CVD deposition blackening layer 5205b may include amorphous silicon by CVD deposition.

### Example 2

In example 2, the reflective metal layer 5205a may be CVD-deposited using aluminum (Al), which is advantageous for low-temperature film formation, and the CVD-deposited blackening layer 5205b may be CVD-deposited using amorphous silicon to form an a-Si/Al/a-Si triple layer, The blackening member 5205 may be CVD-deposited to a thickness of 200 Å, 1000 Å, and 200 Å in the order of a-Si/Al/a-Si, respectively, thereby solving the side step coverage problem.

By chemically depositing aluminum (Al) and amorphous silicon (a-Si) on the sides of multilayer partition members, it may be possible to form a triple-layer blackening member 5205, thereby improving the step coverage that defines the thickness ratio of the deposited layers formed on the upper and lower parts in the depth direction of the microstructure, and using the a-Si/Al/a-Si blackening film, a low-reflection thin-film structure may be formed.

In the light absorption layer barrier rib structure 5200 according to an embodiment of the disclosure, a blackening protective layer 5207 may be formed on the outside of the blackening member 5205 formed on the side of the multilayer film barrier rib member by a chemical vapor deposition method.

The blackening protective layer 5207 may include an inorganic material such as silicon oxide, silicon nitride, silicon oxynitride, aluminum oxide, titanium oxide, tantalum oxide, and hafnium oxide.

### Example 3

In example 3, the blackening protective layer 5207 may be formed of SiO₂ to a thickness of 500 Å.

According to the light absorption layer barrier rib structure 5200 according to an embodiment of the disclosure, the MTO/Mo/MTO triple-layer structure may not be formed using a sputter deposition method, but the blackening member 5205 formed on the side of the multilayer barrier rib member may be formed by chemical vapor deposition, and a low-reflection thin-film structure with excellent step coverage may be formed.

According to an embodiment of the disclosure, by removing the upper and lower parts of the light absorption layer barrier rib structure 5200, the blackening protective layer 5207 may prevent the sides of the absorbent layer barrier rib structure 5200 from being damaged by developer or cleaning solution.

Also, according to an embodiment of the disclosure, the MTO/Mo/MTO triple-layer light absorption layer may be formed on the organic film barrier rib member by the absorption layer barrier rib structure 5200, the organic film barrier rib member may have a problem of instability as being formed by a low-temperature process, but the stability of the barrier rib structure may be secured by a cross-laminated structure of a transparent inorganic layer (SiO₂ or SiNₓ)/transparent organic layer.

FIG. 6 is a schematic cross-sectional view showing the optical path of the light absorption layer barrier rib structure of FIG. 5. As shown in FIG. 6, the light absorption layer barrier rib structure 5200 according to an embodiment of the disclosure may transmit light substantially vertical to pass through the multilayer film barrier rib member stacked alternately with the transparent inorganic layer 5201 and the transparent inorganic layer 5203, and may absorb the obliquely incident internal light and external light by the CVD-deposited amorphous silicon (a-Si) of the blackening member 5205 formed on the side of the multilayer film barrier rib member, which is formed by the CVD deposition blackening layer 5205b.

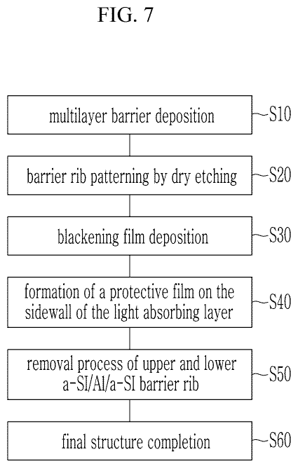

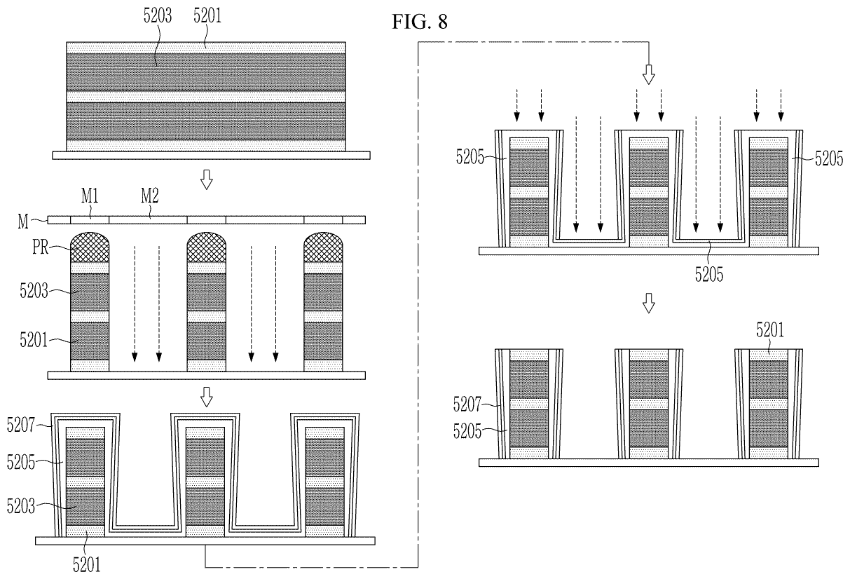

With reference to FIGS. 7 and 8, a method of manufacturing the light absorption layer barrier rib structure 5200 according to an embodiment of the disclosure will be described.

FIG. 7 is a flow chart showing a method of manufacturing a light absorption layer barrier rib structure according to an embodiment of the disclosure, and FIG. 8 is a schematic diagram showing a method of manufacturing a light absorption layer barrier rib structure according to an embodiment of the disclosure.

As shown in FIG. 7, the manufacturing method of the light absorption layer barrier rib structure 5200 according to an embodiment of the disclosure may include constructing a multilayer barrier rib in which transparent inorganic layers and transparent organic layers are alternately stacked on the upper part of the substrate S10, patterning the multilayer barrier rib by dry etching S20, depositing a blackening film on the patterned multilayer barrier rib by chemical vapor deposition to form a blackening member S30, a step of forming a light absorption layer sidewall protective film on the upper part of the blackening member S40, a step of removing the blackening member formed on the top and bottom of the light absorption layer barrier rib structure S50, and a step of finalizing the final light absorption layer barrier rib structure S60.

As shown in FIG. 8, the method for manufacturing the absorption layer barrier rib structure 5200 according to an embodiment of the disclosure may include a step S10 of forming a multilayer barrier rib with transparent inorganic and organic layers alternately stacked on a substrate. In this step, a transparent inorganic layer 5201 may be stacked on the substrate, and a transparent organic layer 5203 may be stacked on top of the transparent inorganic layer 5201. The transparent inorganic layer 5201 may include a silicon nitride compound (SiNₓ), and the transparent organic layer 5203 may include a polyimide-based polymer (PI: polyimide), and using CVD or PECVD methods, the SiNₓ/PI/SiNₓ/PI/SiNₓ multilayer structure may be deposited in increments of 0.5, 3.0, 0.5, 3.0, 0.5K, respectively, to a total thickness of 7.5K.

A step S20 of patterning a multilayer film barrier by dry etching may include applying a photoresist PR on the upper part of the multilayer film barrier rib where a transparent inorganic layer 5201 and a transparent organic layer 5203 are alternately laminated, and using an aligned mask M to expose the photoresist PR to UV light and develop it, only the photoresist PR corresponding to the light absorbing layer barrier rib structure 5200 may be left.

The photoresist PR may be a photosensitive organic material such as an acrylic resin, benzocyclobutene BCB, polyimide PI, and a novolak-based resin.

Here, the photosensitive organic material may be a negative photosensitive material or a positive photosensitive material.

The mask M may include a light blocking portion M1 and a light transmitting portion M2.

The light blocking portion M1 may correspond to an area where the photoresist PR remains, and the light transmitting portion M2 may correspond to an area from which the photoresist PR is removed.

The light blocking portion M1 may be located at a position corresponding to the light blocking area of the substrate 100, and the light transmitting portion M2 may be located at a position corresponding to the pixel area of the substrate 100.

The light absorption layer 520 or the barrier rib 410 may be formed by etching the multilayer barrier rib in the area from which the photoresist PR has been removed.

The etching may be dry etching.

In a step S30 of forming a blackening member by depositing a blackening film on the patterned multilayer barrier rib using a chemical vapor deposition method, the reflective metal layer 5205a may be CVD-deposited using aluminum (Al), which is advantageous for low-temperature film formation, and the blackening layer 5205b may be CVD-deposited using amorphous silicon, and the a-Si/Al/a-Si triple-film blackening member 5205 may be CVD-deposited to a thickness of 200 Å, 1000 Å, and 200 Å in the order of a-Si/Al/a-Si, respectively.

A triple-film blackening member 5205 may be formed on the side of the multi-layer barrier rib member by chemical vapor deposition of aluminum (Al) and amorphous silicon a-Si, so that the step may define the thickness ratio of the deposited layers formed at the top and bottom in the depth direction of the microstructure, while coverage (step coverage) may be improved, and a low-reflection thin-film structure may be formed using a-Si/Al/a-Si blackening film.

In the step of forming the light absorbing layer sidewall protective film on the blackening member S40, the blackening protective layer 5207 may be formed of 500 Å of SiO₂ by chemical vapor deposition.

Subsequently, in the step S50 of removing the blackening members formed on the upper and lower parts of the light-absorbing layer barrier rib structure, the amorphous silicon forming the CVD-deposited blackening film layer 5205b deposited on the upper and lower parts of the light absorption layer barrier rib structure 5200 may be removed by UV exposure or MAH developing solution or cleaning water, and the aluminum reflective metal layer 5205a may be etched by anisotropic dry etching.

Although not shown, after forming a pattern using photoresist and etching using the photoresist pattern to form the pattern, the photoresist may be removed.

The blackening protective layer 5207 may prevent the side surface of the light absorption layer barrier rib structure 5200 from being damaged by a developer or cleaning solution.

The first color conversion layer QD1, the second color conversion layer QD2, and the transmission layer TL may be formed between the light absorption layer barrier rib structures.

Each of the first color conversion layer QD1, the second color conversion layer QD2, and the transmission layer TL may be disposed in the opening formed in the light absorption layer barrier rib structure.

Again, as described above in FIG. 3, the first color conversion layer QD1 may be formed to correspond to the first pixel Pr, the second color conversion layer QD2 may be formed to correspond to the second pixel Pg, and the transmission layer TL may be formed to correspond to the third pixel Pb.

The first color conversion layer QD1, the second color conversion layer QD2, and the transmission layer TL may be formed by, for example, inkjet printing.

A barrier layer 420 may be disposed on the first color conversion layer QD1, the second color conversion layer QD2, and the transmission layer TL.

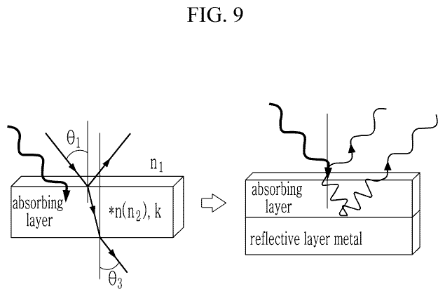

Now, the effect of the light absorption layer barrier rib structure according to an embodiment of the disclosure will be described in detail using FIGS. 9 to 16.

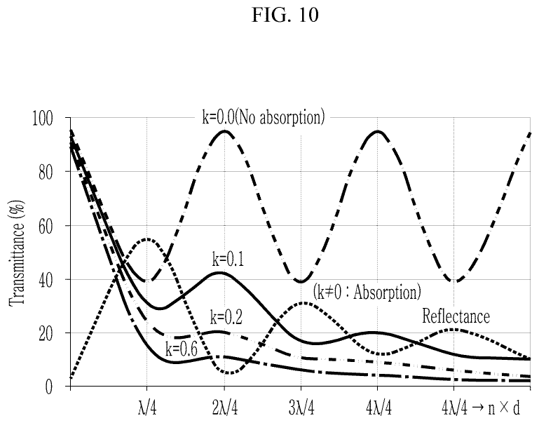

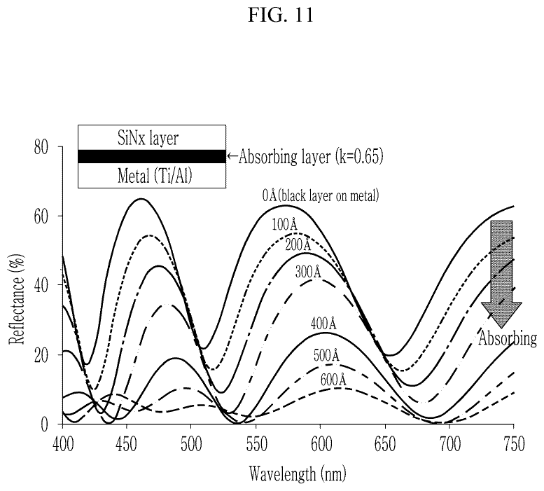

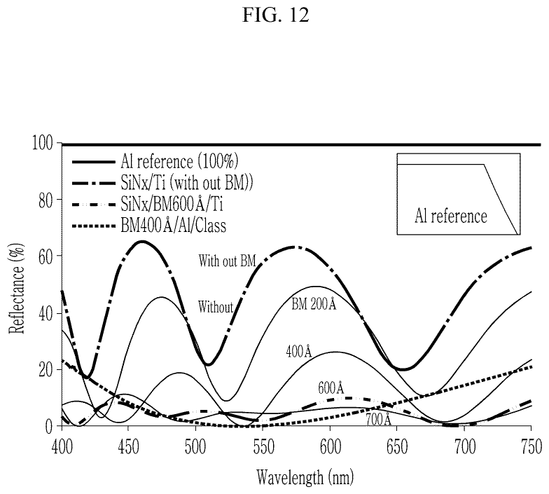

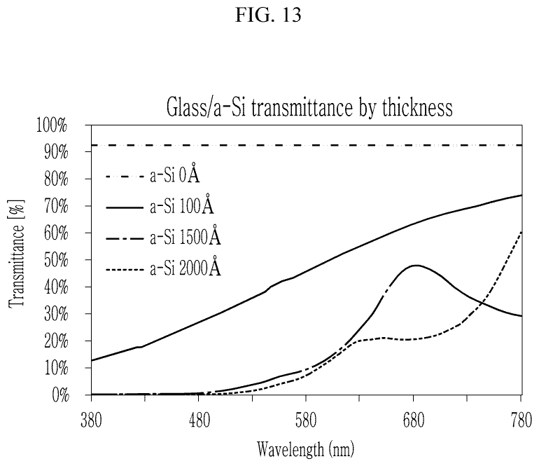

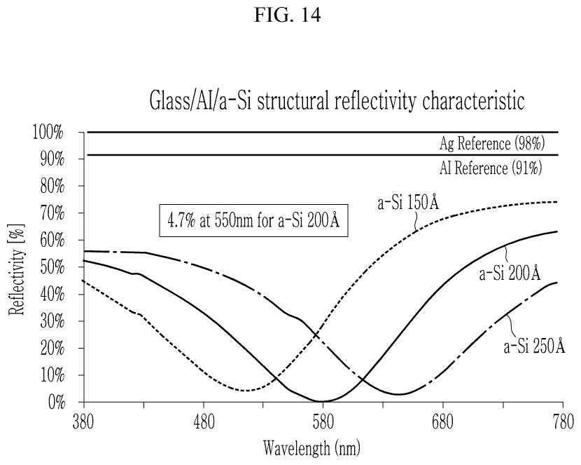

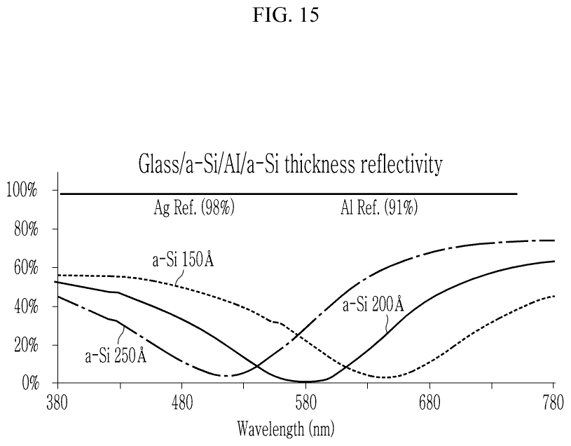

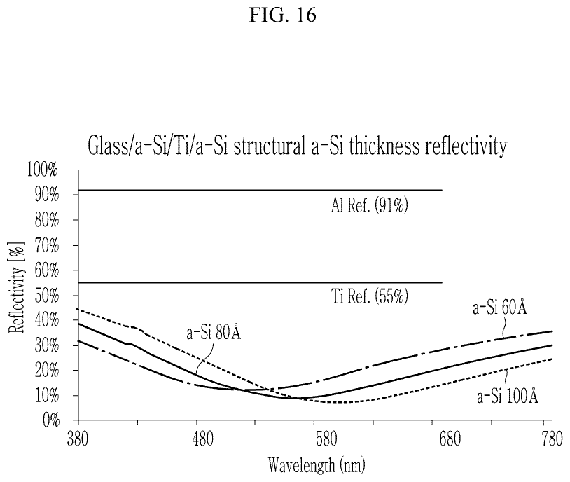

FIG. 9 is a schematic diagram of maximizing the low-reflection effect, FIG. 10 is a graph showing the relationship between the extinction coefficient and transmittance of the medium, FIG. 11 is a graph showing the reflectance according to the thickness of the blackening layer formed on the reflective metal layer, and FIG. 12 is a graph showing the blackening film characteristics due to interference and absorption due to reflection of the metal layer, FIG. 13 is a graph showing the transmittance by a-Si film thickness based on glass, FIG. 14 is a graph showing reflectance by thickness of amorphous silicon film when an amorphous silicon film is formed on an aluminum (Al) reflective metal layer, FIG. 15 is a graph showing reflectance by a-Si thickness of a-Si/Al/a-Si blackening film structure, and FIG. 16 is a graph showing reflectance by a-Si thickness of a-Si/Ti/a-Si blackening film structure.

Referring to FIG. 9, the behavior of incident light between the first and third media with absorption is shown in Equation 1. In Equation 1, θ1 may be an incident angle of light absorbed by the absorption layer, θ3 may be a transmission angle of light that has passed through the absorption layer, n may be a refractive index of the medium, d may be a thickness of the medium film, k may be an absorption coefficient of the medium, T may be a total transmittance, t12 may be a transmittance between the first and second media, t23 may be a transmittance between the second and third media, in case that the third medium has a reflective metal layer, the optical path increases 2 times to 2nd/cos θ, and interference phenomena occur simultaneously with light absorption, which allows obtaining the total transmittance with a thinner film, enabling the configuration of a thinner blackening film.

$$T = \frac{{n}_{2} cos {θ}_{3}}{{n}_{1} cos {θ}_{1}} {\text{?}}_{12}^{2} {\text{?}}_{23}^{2} exp ( - 8 π \frac{kd}{λ} ) \qquad [ Equation 1 ]$$

$${\text{?}}_{12}^{2} = \frac{4 {{n}_{2}^{4} ( 1 + {k}^{2} )}^{2} cos {θ}_{1}^{2}}{{[ {{n}_{2}^{2} ( 1 + {k}^{2} )}^{2} cos {θ}_{1} + {n}_{1} {n}_{2} ]}^{2} + {[ 2 {n}_{2}^{2} k cos {θ}_{1} + {n}_{1} {n}_{2} ]}^{2}}$$

$$\text{?} \text{indicates text missing or illegible when filed}$$

Referring to FIG. 10, in case that the intrinsic absorption coefficient of the medium is 0, no light absorption occurs and all is reflected, but in case that the intrinsic extinction coefficient of the medium is not 0, light absorption occurs and an interference phenomenon occurs at the same time.

In case that the intrinsic extinction coefficient of the medium is not 0, the product n×d of the refractive index n of the medium and the thickness d—for example, as the optical thickness increases, the transmittance decreases—and in the case of a medium with an extinction coefficient of 0.6, even if the optical thickness is not increased, the transmittance decreases, and it can be seen that the transmittance is constant—for example, less than 20%.

FIG. 11 is a graph showing the reflectance according to the thickness of the blackening layer formed on the reflective metal layer, in case that the SiNₓ blackening layer is formed with different thicknesses for the Ti/Al composite reflective metal layer with an absorption coefficient k=0.65, and in case that the reflectance according to the thickness of the SiNₓ blackening layer is investigated, it is found that the Ti/Al composite reflective metal layer may be blackened with an SiNₓ blackening layer in a range of about 500 to 600 Å, with a reflectance greater than or equal to about 65%.

Referring to FIG. 12, in case that the aluminum (Al) reflective metal layer is based on a reflectance of 100%, an SiNₓ/Ti multilayer film in which no blackening film is formed, an SiNₓ/BM600 Å/Ti multilayer film formed in the middle of the blackening film of 600 Å and the BM400 Å/Al/Glass multilayer film in which the blackening film is formed 400 Å, the low reflection effect is maximized in case that a blackening film is formed on the reflective metal layer.

In particular, in the case of the BM400 Å/Al/Glass multilayer film with a blackening film of 400 Å, it can be seen that the ghost reflectance is close to 0 for a wavelength in a range of 500 to 600 nm in case that the aluminum (Al) reflective metal layer is based on a reflectance of 100%.

For example, it can be seen that in case that a thin blackening film is formed on the top of the reflective film of the reflective metal layer, the low-reflection effect is maximized due to the interference effect between the reflective film of the reflective metal layer and the blackening film, thereby ensuring excellent blackening film characteristics.

However, as can be seen in FIG. 12, it may need to optimize the thickness of the light absorption layer barrier rib structure according to different structures according to utilization in the display panel.

For example, it may need to optimize the thickness of the blackening film used as the optical functional layer 510, the wavelength control layer 400, or black matrix.

Referring to FIG. 13, the transmittance as a function of wavelength is plotted for 100 Å, 1500 Å, and 2000 Å of amorphous silicon a-Si film on a glass reference glass substrate with 100% transmittance for glass.

For wavelengths of 480 to 580 nm, it can be seen that the transmittance is almost 10% or less in case that the amorphous silicon a-Si film is formed at 1500 Å or 2000 Å, but for the entire visible light wavelength, the transmittance is less than 10% in case that the amorphous silicon a-Si film is formed at 2000 Å, and it can be seen that it is desirable because it shows a transmittance of 20% or less.

It can be seen that in the case of an amorphous silicon a-Si single film, the light absorption effect is large in case that the thickness is large.

Referring to FIG. 14, based on the reflectance of the reflective film of silver (Ag) or aluminum (Al) reflective metal layers, it can be seen that in case that amorphous silicon a-Si films of 150 Å, 200 Å, and 250 Å are formed on the aluminum (Al) reflective metal layer, the formation of a 200 Å amorphous silicon a-Si film shows a reflectance of 4.7% at a wavelength of 550 nm.

In other words, it can be seen that a low-reflection effect is possible in a thin structure in case that an a-Si blackening film made of amorphous silicon is formed on an aluminum (Al) reflective metal layer.

Referring to FIG. 15, based on the reflectance of the silver (Ag) or aluminum (Al) reflective metal layer, in case that an amorphous silicon a-Si film of 150 Å, 200 Å, and 250 Å is formed on the top and bottom of the aluminum (Al) reflective metal layer, in terms of reflectance by wavelength—for example, in the a-Si/Al/a-Si triple blackening film structure—it can be seen that the reflectance can be less than 5% at 550 nm, which is most sensitive to the eyes.

This is because a low-reflection effect is also observed in the amorphous silicon a-Si film below the aluminum (Al) reflective metal layer, so the a-Si/Al/a-Si triple-layer blackening film structure is symmetrical and shows a same reflection effect on both sides.

Referring to FIG. 16, based on the reflectance of the silver (Ag) or aluminum (Al) reflective metal layer, the amorphous silicon a-Si film was formed on the top and bottom of the titanium (Ti) reflective metal layer with a thickness of 60 Å, 80 Å, and 100 Å. Although the reflectance can be lowered by forming a-Si film thinly, it can be seen that the reflectance for each wavelength band—for example, in the a-Si/Ti/a-Si triple-layer blackening film structure—is possible to have a reflectance of 10% or less at 550 nm, which is most sensitive to the eyes.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device, comprising:
a first light emitting device, a second light emitting device, and a third light emitting device disposed on a substrate;
a first color conversion layer disposed on the first light emitting device and a second color conversion layer disposed on the second light emitting device;
a transmission layer disposed on the third light emitting device; and
a multilayer film barrier rib structure disposed on the first color conversion layer, the second color conversion layer, and the transmission layer, wherein
the multilayer film barrier rib structure includes transparent inorganic layers and transparent organic layers alternately deposited,
a light absorption layer barrier rib structure including a blackening member and a blackening protection member on the blackening member is disposed on a side surface of the multilayer film barrier rib structure, and
the light absorption layer barrier rib structure has a plurality of openings in a first light emitting area of the first light emitting device, a second light emitting area of the second light emitting device, and a third light emitting area of the third light emitting device.

2. The display device of claim 1, wherein
the transparent inorganic layers include a silicon nitride compound, and
the transparent organic layers include an imide-based polymer.

3. The display device of claim 2, wherein
the transparent inorganic layers are deposited to a thickness in a range of about 0.1K to about 1K,
the transparent organic layers are deposited to a thickness in a range of about 2K to about 4K,
and a total height of the multilayer film barrier rib structure is in a range of about 7K to about 9K.

4. The display device of claim 1, wherein
the blackening member comprises a reflective metal layer and a CVD-deposited blackening layer disposed on side surfaces of the reflective metal layer.

5. The display device of claim 4, wherein
the reflective metal layer includes aluminum (Al), which is for low-temperature film formation, and
the CVD-deposited blackening layer includes amorphous silicon.

6. The display device of claim 5, wherein
the reflective metal layer has a thickness in a range of about 100 Å to about 300 Å, and
the CVD-deposited blackening layer has a thickness in a range of about 500 Å to about 1,500 Å.

7. The display device of claim 1, wherein the blackening protective member includes SiO₂ and is deposited by CVD to a thickness in a range of about 300 Å to about 600 Å.

8. A light absorption layer barrier rib structure, comprising:
a multilayer barrier rib structure including a transparent inorganic layer and a transparent organic layer alternately deposited;
a blackening member CVD-deposited on a side surface of the multilayer barrier rib structure; and
a blackening protection member on the blackening member.

9. The light absorption layer barrier rib structure of claim 8, wherein
the transparent inorganic layer includes a silicon nitride compound, and
the transparent organic layer includes an imide-based polymer.

10. The light absorption layer barrier rib structure of claim 9, wherein:
the transparent inorganic layer is deposited to a thickness in a range of about 0.1K to about 1K,
the transparent organic layer is deposited to a thickness in a range of about 2K to about 4K, and
a total height of the multilayer barrier rib member is in a range of about 7K to about 9K.

11. The light absorption layer barrier rib structure of claim 8, wherein
the blackening member comprises a reflective metal layer and a CVD-deposited blackening layer disposed on side surfaces of the reflective metal layer.

12. The light absorption layer barrier rib structure of claim 11, wherein
the reflective metal layer includes aluminum (Al), which is for low-temperature film formation, and
the CVD-deposited blackening layer includes amorphous silicon.

13. The light absorption layer barrier rib structure of claim 12, wherein
the reflective metal layer has a thickness in a range of about 100 Å to about 300 Å, and
the CVD-deposited blackening layer has a thickness in a range of about 500 Å to about 1500 Å.

14. The light absorption layer barrier rib structure of claim 8, wherein the blackening protection member includes SiO₂, and is a light absorption layer barrier rib structure CVD-deposited to a thickness in a range of about 300 Å to about 600 Å.

15. A method of manufacturing a light absorption layer barrier rib structure, comprising:
constructing a multilayer barrier rib member in which transparent inorganic layers and transparent organic layers are alternatively arranged on an upper part of a substrate by CVD deposition;
patterning the multilayer barrier rib member by dry-etching to form a patterned multilayer barrier rib member;
forming a blackening member by CVD deposition on the patterned multilayer barrier rib member;
forming a blackening member protective film on the blackening member by CVD deposition; and
removing the blackening member on an upper portion and a lower portion of the multilayer barrier rib member by anisotropic dry-etching.

16. The method of manufacturing the light absorption layer barrier rib structure of claim 15, wherein
the constructing of the multilayer barrier rib member includes stacking the transparent inorganic layers on the substrate, and stacking the transparent organic layers on top of the transparent inorganic layers,
the transparent inorganic layers include a silicon nitride compound,
the transparent organic layers include an imide-based polymer,
the forming of the blackening member includes CVD-depositing a reflective metal layer using aluminum (Al), and CVD-depositing a blackening layer using amorphous silicon, and
forming of the blackening member protective film includes forming the blackening member protective film using SiO₂ by CVD deposition.

17. A method of manufacturing a display device, comprising:
forming a first light emitting device, a second light emitting device, and a third light emitting device on a substrate;
forming a first color conversion layer on the first light emitting device, a second color conversion layer on the second light emitting device, and a transmission layer on the third light emitting device;
forming a light absorption layer barrier rib structure comprising a multilayer film barrier rib structure, which is alternately deposited with a transparent inorganic layer and a transparent organic layer, on the first color conversion layer, the second color conversion layer, and the transmission layer; and
CVD-depositing a blackening member on a side surface of the multilayer film barrier rib structure, and a blackening protection member on the blackening member,
wherein an aperture ratio of a plurality of openings formed in the light absorption layer barrier rib structure respectively corresponding to the first light emitting device, the second light emitting device, and the third light emitting device are different.

18. The method of manufacturing the display device of claim 17, wherein the forming of the light absorption layer barrier rib structure comprises:
constructing a multilayer barrier rib member in which the transparent inorganic layer and the transparent organic layer are alternatively disposed on the substrate by CVD deposition;
patterning the multilayer barrier rib member by dry etching to form a patterned multilayer barrier rib member;
forming a blackening member by CVD deposition on the patterned multilayer barrier rib member;
forming a blackening member protective film on the blackening member by CVD deposition; and
removing the blackening member on an upper portion and a lower portion of the multilayer barrier rib member by anisotropic dry etching.

19. The method of manufacturing the display device of claim 18, wherein:
the forming of the blackening member comprises CVD depositing a reflective metal layer using aluminum (Al), and a blackening layer using amorphous silicon.

20. The method of manufacturing the display device of claim 19, wherein
the constructing of the multilayer barrier rib structure includes constructing a multilayer structure in which the transparent inorganic layer is stacked on the substrate and the transparent organic layer is stacked on top of the transparent inorganic layer,
the transparent inorganic layer includes silicon nitride compound,
the transparent organic layer includes an imide-based polymer, and
the forming of the blackening member protective film includes forming the blackening member protective film using SiO₂ by CVD deposition.
